(19) United States
(12) Patent Application Publication
(10) Pub. No.: US 2006/0284288 A1
(43) Pub. Date: Dec. 21, 2006

(54) Wafer and single chip having circuit rearranged structure and method for fabricating the same

(76) Inventor: Chu-Chin Hu, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/449,252

(22) Filed: Jun. 7, 2006

(30) Foreign Application Priority Data
Jun. 17, 2005 (TW) 094120143

(51) Int. Cl. H01L 23/495

(52) U.S. Cl. 257/668

(57) ABSTRACT

A wafer and single chip having a circuit rearranged structure and method for fabricating the same are proposed. A wafer having a plurality of chips is provided. Each of the chip has an active surface having a plurality of electrode pads. A dielectric layer is formed on the active surface. The dielectric layer is thinned to expose the electrode pads. A conducting layer is formed on the dielectric layer and the electrode pads. A first metal layer is formed on the conductive layer by electroplating. A patterned second metal layer is formed on the first metal layer by printing. Using the second metal layer as a protecting layer, the first metal layer and the conducting layer are etched and part uncovered by the second metal layer are removed. The second and the remaining first metal layer form a circuit rearranged structure electrically connected to the electrode pads.

### CROSS-REFERENCE TO RELATED APPLICATION

This application claims benefit under 35 USC 119 to Taiwan Application No. 094120143, filed Jun. 17, 2005.

### FIELD OF THE INVENTION

This invention relates to wafers and singles chip having a circuit rearranged structure and methods for fabricating the same, and more particularly, to a wafer fabricating method for forming a circuit on a wafer directly.

### BACKGROUND OF THE INVENTION

With the development of semiconductor packaging techniques, semiconductors come to the market in varieties of packages. However, most of the semiconductor packages are manufactured by fixing a semiconductor chip on a substrate first, then electrically connecting the semiconductor chip to the substrate, and finally using a resin to encapsulate the semiconductor chip or injecting resin into gaps between the semiconductor chip and the substrate to fabricate a packaging process.

The ways to electrically connect the semiconductor chip to the substrate includes a wire bonding package and a flip chip bonding package, which is more advanced than the wire bonding package. The flip chip bonding package has to form electrode pads on the semiconductor chip in advance. In a process to the bond pads on the semiconductor chip, a passivation layer is formed on the semiconductor chip for exposure of the electrode pads. An under bump metallurgy (UBM) structure having a plurality of stacked metal layers is formed on the electrode pads by sputtering and electroplating processes. A light sensitive insulation layer is installed on the passivation layer. The light sensitive insulation layer comprises a plurality of openings for exposure of the UBM structure. A solder printing process is performed thereafter. For example, a solder material made of an alloy of tin and lead is painted through the openings of the passivation layer onto the UBM structure by a screen printing technique, and fixed to the UBM structure by a reflow process. The passivation layer is then removed. The solder material is rounded again by the reflow process, so as to form on the semiconductor chip metal bumps, which can be electrically connected to a circuit board.

The wire bonding package adopts different manufacturing equipments and processes to manufacture the circuit board and fabricate the semiconductor chip package, so the wire bonding package process is complicated. Moreover, during a molding and resin injecting process, the circuit board, on which the semiconductor chip has been installed, is placed in a package mold, for an epoxy resin material to be injected into the package mold to form a package resin to cover the semiconductor chip and solder wires. However, in practice, the package mold is restricted by the semiconductor package, so a clapping position and the size of an intra-cavity of the package mold are varied, resulting in an loosely fixing problem. After the resin material is injected into the package, the package resin overflows easily to the circuit board, degrading the flatness and appearance of the semiconductor package, and even contaminating ball pad location where the solder balls are planted on the circuit board. In result, the semiconductor package has only a poor electric connection quality, which severely impact the production quality and production reliability of the semiconductor package.

Moreover, the semiconductor chips of the semiconductor packages of the prior art are adhered to a top surface of the substrate directly and packaged by the resin material, and solder balls are planted on a bottom surface of the substrate. Such a stacked structure increases the height of the semiconductor package.

As to an general semiconductor component manufacturing process, a chip carrier manufacturer first produces chip carriers, such as substrates or lead frames, which are suitable for the semiconductor components, and semiconductor packaging manufacturers then perform die-placing, molding and ball-planting processes on the chip carriers, so as to complete the semiconductor components, which have certain functions required by clients. According to such scenario, the chip carrier manufacturer and the semiconductor packaging manufacturer have to work closely to solve the problems resulting from too complicate the processes and too hard to integrate the processes. Moreover, if the client plans to change the design of the semiconductor components, both the chip carrier manufacturer and the semiconductor packaging manufacturer are involved and have to spend more time on the change and integration of the manufacturing processes.

Although a wafer level chip size package has been introduced to the market, which forms circuit connection of electrode pads of the semiconductor chip by forming a dielectric layer on a wafer and by the use of a photolithography process, and the wafer level chip size package indeed reduces the size of the semiconductor package, the photolithography process can not perform well if the circuit connection is not positioned accurately, and will consume a lot of materials.

### SUMMARY OF THE INVENTION

In views of the above-mentioned problems of the prior art, it is a primary objective of the present invention to provide a wafer and single chip having a circuit rearranged structure and a method for fabricating the same, so as to form a circuit on a wafer body and get rid of the use of the chip carrier.

It is another objective of the present invention to provide a wafer and single chip having a circuit rearranged structure and a method for fabricating the same, so as to reduce the size of the wafer and the single chip.

It is a further objective of the present invention to provide a wafer and single chip having a circuit rearranged structure and a method for fabricating the same through the use of a screen printing technique, without the use of a plurality of complicated processes, such as photolithography and electroplating processes, to form a circuit structure.

To achieve the above-mentioned and other objectives, a wafer and single chip having a circuit rearranged structure and a method for fabricating the same are provided according to the present invention. The method includes providing a wafer comprising a plurality of chips, each of the chips having an active surface having a plurality of electrode pads; forming a dielectric layer on the active surface; thinning the dielectric layer to expose the electrode pads; forming a conductive layer on the dielectric layer and the electrode pad; electroplating and forming a first metal layer on the conductive layer; forming a pattered second metal layer on the first metal layer; and removing part of the first metal layer and conductive layer uncovered by the second metal layer.

The method further includes forming a build-up circuit structure by iterating the above processes, forming a solder mask on the build-up circuit structure, forming a plurality of openings on the solder mask for exposure of part of the outermost circuit, and forming in the openings a plurality of conductive components electrically connected to the part of the outermost circuit, so as to form a circuit rearranged structure.

According to the above-mentioned method, the present invention further provides a wafer having a circuit rearranged structure. The wafer includes a wafer body comprising a plurality of chips, each of the chips having an active surface having a plurality of electrode pads; a dielectric layer formed on the active surface, the dielectric pads of the chips being exposed through the dielectric layer to a region outside of the wafer body; a conductive layer formed on the dielectric layer and electrically connected to the electrode pads; a first metal layer electroplated and formed on the conductive layer; and a second metal layer printed and formed on the first metal layer, the second metal and the first metal layer forming a circuit rearranged structure electrically connected to the electrode pads of the chips.

According to the above-mentioned structure, the present invention further provides a single chip having a circuit rearrange structure. The single chip includes a chip body having an active surface and a plurality of electrode pads formed on the active surface; a dielectric layer formed on the active surface, the electrode pads being exposed through the dielectric layer to a region outside of the chip body; a conductive layer formed on the electrode pad; a first metal layer electroplated and formed on the conductive layer; and a second metal layer printed and formed on the first metal layer, the second metal layer and the first metal layer forming a circuit rearranged structure electrically connected to the electrode pads.

Since having the circuit rearranged structure, which is formed directly on the wafer body, the wafer needs neither under bump metallurgy (UBM) nor chip carrier connecting circuits such as a circuit board, and has a compact size and low manufacturing cost. Moreover, forming the circuit arranged structure directly on the wafer body allows the wafer to have a better change flexibility, so as to simplify the difficulty of integration and integrate a process of wafer fabrication and the semiconductor chip package to reduce manufacturing cost. Further, the present invention provides a method for forming a wafer integration circuit structure by the use of a screen printing technique, without the use of a plurality of complicated processes, such as a photolithography process and an electroplating process.

### BRIEF DESCRIPTION OF DRAWINGS

The invention can be more fully understood by reading the following detailed description of the preferred embodiments, with reference made to the accompanying drawings, wherein:

FIGS. 1A to 1K are eleven cross sectional views of a wafer having a circuit rearranged structure according to the present invention;

FIG. 2 is a top view of the wafer shown in FIG. 1B;

FIG. 3A is a top view of the wafer shown in FIG. 1F;

FIG. 3B is a top view of the wafer shown in FIG. 1H;

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

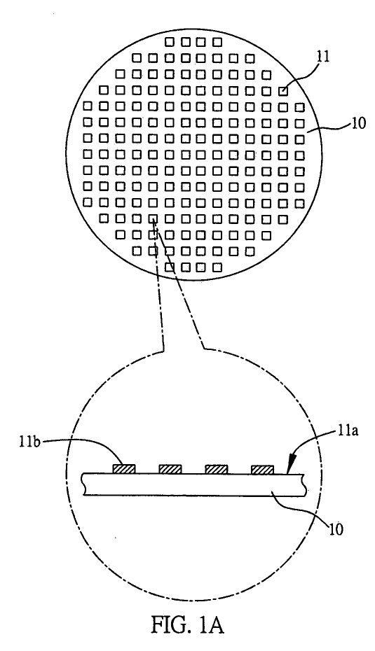

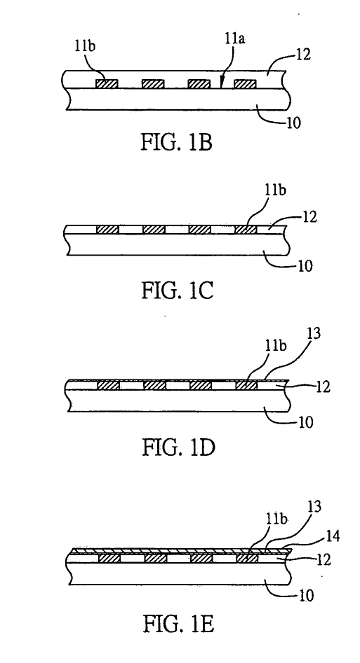

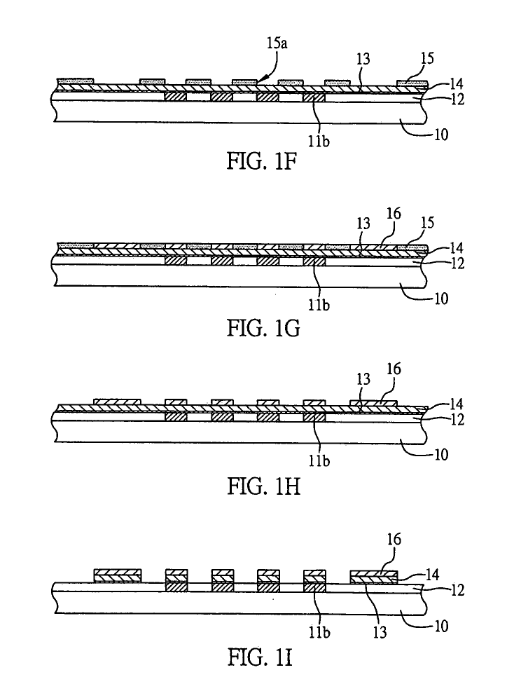

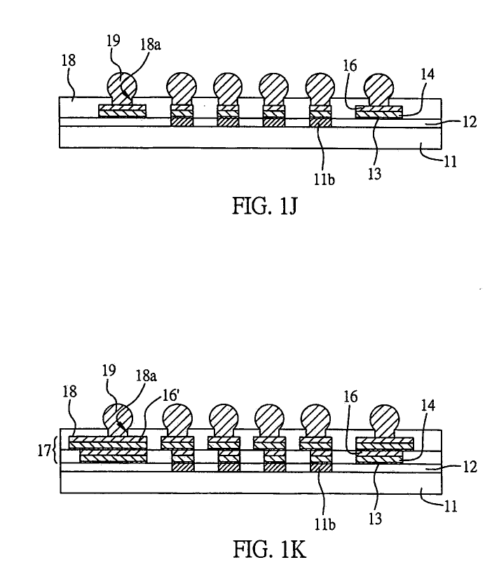

FIGS. 1A to 1K are eleven cross sectional views demonstrating a wafer fabricating method for fabricating a wafer having a circuit rearranged structure according to the present invention.

Please refer to FIG. 1A. The method first provides a wafer body 10, which comprises a plurality of single chips 11. Each of the chips 11 comprises an active surface 11a, and a plurality of electrode pads 11b disposed on the active surface 11a.

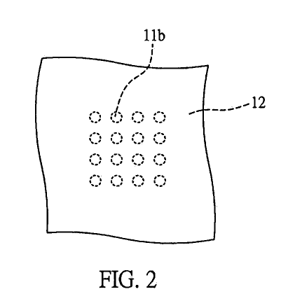

Please refer to FIG. 1B. The method electroplates a dielectric layer 12 on the active surface 11a to cover the electrode pads 11b, as shown in FIG. 2, which is a top view of the wafer body 10 in FIG. 1B.

Please refer to FIG. 1C. The method performs a thinning process on the dielectric layer 12 to thin the dielectric layer 12, to expose the electrode pads 11b of the wafer body 10.

Please refer to FIG. 1D. The method then forms a conductive layer 13 on the dielectric layer 12 and the electrode pads 11b. According to the embodiment, the conductive layer 13 is made of metal, alloy, or conductive polymer materials, and has a multiple-layered structure.

Please refer to FIG. 1E. Taking the use of the conductive property of the conductive layer 13 and regarding the conductive layer 13 as a current conductive route when an electroplating process is performed, the method performs the electroplating process on the conductive layer 13 and forms a first metal layer 14, which is preferably made of copper. The first metal layer 14 is electroplated by the use of the conductive layer 13 to form a thick metal structure, which prevents the wafer body 10 from generating a peeling off phenomenon during succeeding manufacturing processes for forming a circuit structure.

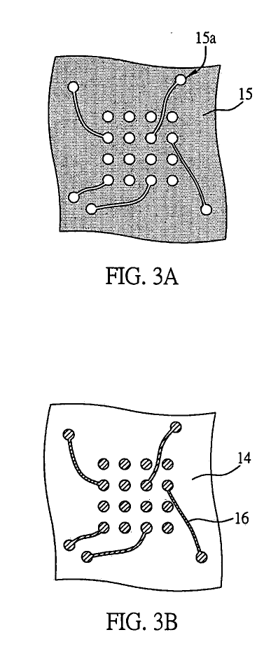

Please refer to FIGS. 1F and 1G. The method then covers on the first metal layer 14 a stencil 15 having a plurality of openings 15a corresponding to the electrode pads 11b, as shown in FIG. 3A, which is a top view of the wafer body 10 in FIG. 1F. The method prints and forms a second metal layer 16 in a plurality of the openings 15a of the stencil 15. The second metal layer 16 is preferably made of tin.

Please refer to FIG. 1H. The method then removes the stencil 15 to form a patterned second metal layer 16, as shown in FIG. 3B, which is a top view of the wafer body 10 in FIG. 1H.

Please refer to FIG. 1I. Taking the second metal layer 16 as a protecting layer, the method etches and removes part of the first metal layer 14 and conductive layer 13 uncovered by the second metal layer 13. A circuit structure formed by the remaining second metal layer 16 and first metal layer 14 after etching is electrically connected to the electrode pads 11b of the wafer body 10.

Please refer to FIG. 1J. The method further forms a solder mask 18 on a surface of the circuit structure formed by the second metal layer 16 and first metal layer 14. A plurality of openings 18a are formed on the solder mask 18 for exposure of the second metal layer 16, the outermost layer of the circuit structure. Therefore, a plurality of conductive components 19 can be formed in the openings 18a. After dices sawing, the wafer body 10 becomes a plurality of chips 11.

Please refer to FIG. 1K. The method, by iterating the above processes, further forms a build-up circuit structure 17 between the dielectric layer 12 and the second metal layer 16, and forms on the build-up circuit structure 17 a solder mask 18 having a plurality of openings 18a for exposure of the second metal layer 16′, an outermost layer. Therefore, a plurality of conductive components 19 can be formed in the openings 18a. After dices sawing, the wafer body 10 becomes a plurality of chips 11, the build-up circuit structure 17 having multiple layers being formed on the active surface 11a.

According to the above method, the present invention provides a wafer having a circuit rearranged structure. The wafer comprises a wafer body 10 having a plurality of chips 11, each of which having an active surface 11a. Each of the active surfaces 11a comprises a plurality of electrode pads 11b. A dielectric layer 12 is formed on the active surface 11a of the wafer body 10. The electrode pads 11b of the wafer body 10 are exposed from the dielectric layer 12 to a region outside of the wafer body 10. A conductive layer 13 is formed on the electrode pads 11b. A first metal layer 14 is electroplated on the conductive layer 13. A second metal layer 16 is printed and formed on the first metal layer. A circuit structure formed by the second metal layer 16 and first metal layer 14 is electrically connected to the electrode pads 11b of the wafer body 10.

Further, the present invention, according to the above method, provides a chip 11 having a circuit rearranged structure. The chip 11 has an active surface 11a, a plurality of electrode pads 11b formed on the active surface 11a, a dielectric layer 12 formed on the active surface 11a and exposing the electrode pad 11b, a conductive layer 13 formed on the electrode pads 11b, a first metal layer 14 electroplated and formed on the conductive layer 13, and a second metal layer 16 printed and formed on the first metal layer 14. A circuit structure formed by the second metal layer 16 and first metal layer 14 is electrically connected to the electrode pads 11b of the chip 11.

Since having the circuit rearranged structure, which is formed directly on the wafer body, the wafer needs neither under bump metallurgy (UBM) nor chip carrier such as a circuit board, and has a compact size and low manufacturing cost. Moreover, forming the circuit arranged structure directly on the wafer body allows the wafer to have a better change flexibility, so as to simplify the difficulty of integration and integrate a process of wafer fabrication and the semiconductor chip package to reduce manufacturing cost. Further, the present invention provides a method for forming a wafer integration circuit structure by the use of a screen printing technique, without the use of a plurality of complicated processes, such as a photolithography process and an electroplating process.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A wafer fabricating method for fabricating a wafer having a circuit rearranged structure, the method comprising:
providing a wafer comprising a plurality of chips, each of the chips having an active surface having a plurality of electrode pads;
forming a dielectric layer on the active surface;
thinning the dielectric layer to expose the electrode pads;
forming a conductive layer on the dielectric layer and the electrode pads;
electroplating and forming a first metal layer on the conductive layer;
forming a pattered second metal layer on the first metal layer; and
removing part of the first metal layer and conductive layer uncovered by the second metal layer.

2. The method of claim 1, wherein the patterned second metal layer is formed by covering on the first metal layer a stencil having a plurality of openings corresponding to the electrode pads to print metal material onto the stencil to form a second metal layer, and by removing the stencil.

3. The method of claim 1, wherein the second metal layer is a protecting layer, which is formed by etching the part of the first metal layer and conductive layer uncovered by the second metal layer.

4. The method of claim 1 further comprising forming a build-up circuit structure on the dielectric layer and the second metal layer.

5. The method of claim 4 further comprising forming a solder mask on the build-up circuit structure, and forming a plurality of openings for exposure of the second metal layer of the build-up circuit structure.

6. The method of claim 5 further comprising forming in the solder mask openings a plurality of conductive components electrically connected to the second metal layer.

7. The method of claim 1 further comprising forming on the dielectric layer and the second metal layer a solder mask having a plurality of openings for exposure of the second metal layer.

8. The method of claim 7 further comprising forming in the opening of the solder mask a plurality of conductive components electrically connected to the second metal layer.

9. The method of claim 1 further comprising dividing the wafer into a plurality of chips.

10. A wafer having a circuit rearranged structure, the wafer comprising:
a wafer body comprising a plurality of chips, each of the chips having an active surface having a plurality of electrode pads;
a dielectric layer formed on the active surface, the electrode pads of the chips being exposed through the dielectric layer;
a conductive layer formed on the dielectric layer and electrically connected to the electrode pads;
a first metal layer electroplated and formed on the conductive layer; and
a second metal layer printed and formed on the first metal layer, the second metal and the first metal layer forming a circuit rearranged structure electrically connected to the electrode pads of the chips.

11. The wafer of claim 10 further comprising a build-up circuit structure formed on the active surface and the second metal layer.

12. The wafer of claim 11 further comprising a solder mask formed on the build-up circuit structure, and a plurality of openings for exposure of the second metal layer of the build-up circuit structure.

13. The wafer of claim 12 further comprising a plurality of conductive components formed in the solder mask openings and electrically connected to the second metal layer.

14. The wafer of claim 10 further comprising a solder mask formed on the dielectric layer and second metal layer, and a plurality of openings for exposure of the second metal layer.

15. The wafer of claim 14 further comprising a plurality of conductive components formed in the solder mask openings and electrically connected to the second metal layer.

16. A chip having a circuit rearranged structure, the chip comprising:
a chip body having an active surface and a plurality of electrode pads formed on the active surface;
a dielectric layer formed on the active surface, the electrode pads being exposed through the dielectric layer;
a conductive layer formed on the electrode pads;
a first metal layer electroplated and formed on the conductive layer; and
a second metal layer printed and formed on the first metal layer, the second metal layer and the first metal layer forming a circuit rearranged structure electrically connected to the electrode pads.

17. The chip of claim 16 further comprising a build-up circuit structure formed on the active surface and the second metal layer.

18. The chip of claim 17 further comprising a solder mask formed on the build-up circuit structure, and a plurality of openings for exposure of the second metal layer of the build-up circuit structure.

19. The chip of claim 18 further comprising a plurality of conductive components formed in the solder mask openings and electrically connected to the second metal layer.

20. The chip of claim 16 further comprising a solder mask formed on the dielectric layer and the second metal layer, and a plurality of openings for exposure of part of the second metal layer.

21. The chip of claim 20 further comprising a plurality of conductive components formed in the solder mask openings and electrically connected to the second metal layer.
